(19) United States
(12) Patent Application Publication
(10) Pub. No.: US 2024/0332102 A1
(43) Pub. Date: Oct. 3, 2024

(54) PACKAGE WITH ENCAPSULANT AND FURTHER ENCAPSULANT THEREON

(71) Applicant: Infineon Technologies AG, Neubiberg (DE)

(72) Inventors: Stefan SCHWAB, Wald (DE); Yosephine ANDRIANI, Central Java (ID)

(73) Assignee: Infineon Technologies AG, Neubiberg (DE)

(21) Appl. No.: 18/584,286

(22) Filed: Feb. 22, 2024

(30) Foreign Application Priority Data
Mar. 28, 2023 (DE) 10 2023 202 833.6

(51) Int. Cl. H01L 23/29; H01L 21/56; H01L 23/00; H01L 23/31; H01L 23/373

(52) U.S. Cl. CPC H01L 23/295; H01L 21/56; H01L 23/3135; H01L 23/3735; H01L 24/48; H01L 2224/48175

(57) ABSTRACT

A package is disclosed. In one example, the package comprises a carrier, an electronic component mounted on the carrier, an encapsulant comprising not more than 0.1 weight percent, in relation to an entire weight of the encapsulant, of electrically conductive particles. The encapsulant at least partially encapsulates the electronic component and the carrier. A further encapsulant is provided covering an exterior surface of at least part of the encapsulant and having a larger amount of electrically conductive material than the encapsulant.

### CROSS-REFERENCE TO RELATED APPLICATION

This Utility Patent application claims priority to German Patent Application No. 10 2023 202 833.6 filed Mar. 28, 2023, which is incorporated herein by reference.

### BACKGROUND

### Technical Field

Various embodiments relate generally to a package, and a method of manufacturing a package.

### Description of the Related Art

A conventional package may comprise an electronic component mounted on a chip carrier such as a leadframe, may for example be electrically connected by a bond wire extending from the chip to the chip carrier or to a lead, and may be molded using a mold compound as an encapsulant.

Electric reliability of a conventional package may be an issue.

### SUMMARY

There may be a need for a package with high electric reliability.

According to an exemplary embodiment, a package is provided which comprises a carrier, an electronic component mounted on the carrier, an encapsulant comprising not more than 0.1 weight percent, in relation to an entire weight of the encapsulant, of electrically conductive particles, wherein the encapsulant at least partially encapsulates the electronic component and the carrier, and a further encapsulant covering an exterior surface of at least part of the encapsulant and having a larger amount of electrically conductive material than the encapsulant.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of a package according to an exemplary embodiment.

FIG. 2 illustrates a flowchart of a method of manufacturing a package according to an exemplary embodiment.

FIG. 3 illustrates a cross-sectional view of a package according to another exemplary embodiment.

FIG. 4 illustrates a three-dimensional view of a preform of a package according to another exemplary embodiment.

FIG. 5 illustrates a constituent of a package according to another exemplary embodiment.

FIG. 6 to FIG. 8 illustrate diagrams showing effects of exemplary embodiments over conventional approaches.

FIG. 9 illustrates structures obtained during manufacturing a package according to an exemplary embodiment.

FIG. 10 illustrates structures obtained during manufacturing a package according to another exemplary embodiment.

### DETAILED DESCRIPTION

According to an exemplary embodiment, a package is provided which comprises a carrier, an electronic component mounted on the carrier, an encapsulant comprising not more than 0.1 weight percent, in relation to an entire weight of the encapsulant, of electrically conductive particles, wherein the encapsulant at least partially encapsulates the electronic component and the carrier, and a further encapsulant covering an exterior surface of at least part of the encapsulant and having a larger amount of electrically conductive material than the encapsulant.

According to another exemplary embodiment, a method of manufacturing a package is provided, the method comprising mounting an electronic component on a carrier, at least partially encapsulating the electronic component and the carrier by an encapsulant which comprises not more than 0.1 weight percent, in relation to an entire weight of the encapsulant, of electrically conductive particles, and forming a further encapsulant at an exterior surface of at least part of the encapsulant, wherein the further encapsulant has a larger amount of electrically conductive material than the encapsulant.

According to an exemplary embodiment, a package comprises a carrier on which an electronic component is mounted. A first encapsulant having not more than 0.1 weight percent electrically conductive particles (or generally electrically conductive material) may encapsulate the electronic component and the carrier. In addition, a second encapsulant may cover the first encapsulant at least partially and may have a larger amount of electrically conductive material (or specifically electrically conductive particles). Advantageously, such a package design may lead to a high electric reliability. The interior first encapsulant, which may be depleted of electrically conductive particles (such as carbon black), may result in an improved breakdown voltage and an improved long-term high voltage stability. At the same time, a low amount of or even the absence of electrically conductive particles in the interior first encapsulant may advantageously reduce the tendency of corrosion and may improve adhesion of the constituents in contact with the first encapsulant. Further advantageously, surrounding the first interior encapsulant at least partially by a second exterior encapsulant with a larger amount of electrically conductive particles (for example carbon black) may provide the package with an improved electrostatic discharge (ESD) protection without compromising the advantageous effects of the interior first encapsulant concerning electric reliability. To put it shortly, the electrically conductive material (in particular electrically conductive particles) of the second encapsulant may contribute to a removal of charge carriers from the package, so that the package may be protected against undesired electric charging. Furthermore, providing the exterior encapsulant with electrically conductive particles (such as carbon black) may render the exterior surface of the package suitable for laser marking, which may be promoted by carbon black or the like. In a preferred embodiment, a core encapsulant may be provided with less electrically conductive particles than a surrounding shell encapsulant. This may allow to obtain a package having the above-mentioned advantages in combination.

In the following, further exemplary embodiments of the package and the method will be explained.

In the context of the present application, the term “package” may particularly denote an electronic device which may comprise one or more electronic components mounted on a (in particular partially or entirely electrically conductive) carrier. Said constituents of the package may be encapsulated at least partially by an encapsulant. Optionally, one or more electrically conductive connection elements (such as metallic pillars, pumps, bond wires and/or clips) may be implemented in a package, for instance for electrically coupling and/or mechanically supporting the electronic component.

In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and optionally an electric connection function. A carrier may comprise or consist of a single part, multiple parts joined via encapsulation or other package components, or a subassembly of carriers. When the carrier forms part of a leadframe, it may be or may comprise a die pad. For instance, such a carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate. Also at least part of the carrier may be encapsulated by the encapsulant, together with the electronic component.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed in silicon technology, gallium nitride technology, silicon carbide technology, etc.

In the context of the present application, the term “encapsulant” may particularly denote a material, structure or member surrounding at least part of an electronic component and at least part of a carrier to provide mechanical protection, and optionally electrical insulation and/or a contribution to heat removal during operation. In particular, said encapsulant may be predominantly or even entirely electrically insulating, for instance a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

In the context of the present application, the term “further encapsulant” may in particular denote a material, structure or member at least partially covering or surrounding the above-mentioned first or interior encapsulant. Hence, the further encapsulant may be an exterior encapsulant. The further encapsulant may be for example a further mold compound or may be an electronic member (such as a further carrier, for instance a ceramic sheet covered on both opposing main surfaces by a metallic layer) to thereby function as an encapsulating entity with respect to the first or interior encapsulant.

In the context of the present application, the term “electrically conductive particles” may in particular denote particles being distributed inside of a matrix material (for example a dielectric mold compound) of the assigned encapsulant and having an electrically conductive property. The electrically conductive particles may be connected with or may be unconnected with respect to other electrically conductive particles. An electrically conductive property may correspond to an electric conductivity (at 20° C.) of at least 0.01 S/cm, in particular of at least 0.05 S/cm, preferably of at least 0.1 S/cm, for example at least 1 S/cm. In particular, electrically conductive particles may comprise carbon, in particular carbon black, and/or a metallic material. For example, the electrically conductive particles may be shaped as beads, spheres, cuboids and/or flakes, etc.

In the context of the present application, the term “electrically conductive material” may in particular denote electrically conductive particles, as described above, or a continuous or patterned electrically conductive structure, such as a metallic layer.

In the context of the present application, the term “carbon black” may in particular denote a fine carbon powder which may be made by burning hydrocarbons in insufficient air. More specifically, carbon black may denote a material which may be produced by the incomplete combustion of coal and coal tar, vegetable matter, or petroleum products, including fuel oil, fluid catalytic cracking tar, and ethylene cracking in a limited supply of air. Carbon black may be a black, finely divided form of amorphous carbon.

In an embodiment, the encapsulant comprises electrically conductive particles, for example carbon black, in a range from 0.025 weight percent to 0.05 weight percent in relation to the entire weight of the encapsulant. In the mentioned small amount, electrically conductive particles such as carbon black may still contribute to ESD protection and/or laser marking capability while showing a proper electric breakdown voltage and time-dependent dielectric breakdown (TDDB) behavior.

In another embodiment, the encapsulant is free of electrically conductive particles. A skilled person will understand that an encapsulant being free of electrically conductive particles may still have an unavoidable residue of electrically conductive particles due to manufacturing tolerances and the like. Being substantially free of electrically conductive particles, the encapsulant may have an excellent electric breakdown voltage and an advantageous TDDB behavior.

In an embodiment, the encapsulant comprises not more than 0.05 weight percent, in relation to the entire weight of the encapsulant, of carbon black as the electrically conductive particles. Such a small amount of carbon black may be acceptable in terms of electric reliability and may even contribute to ESD protection and/or laser marking capability.

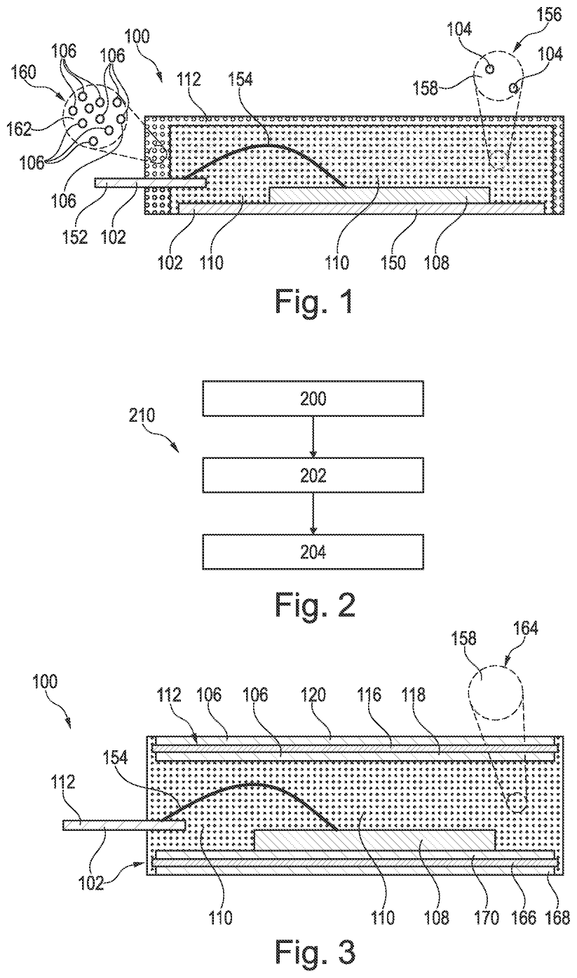

In an embodiment, the electrically conductive material of the further encapsulant comprises electrically conductive particles such as carbon black (see for instance FIG. 1) or comprises at least one metal layer (compare for example FIG. 3). Such electrically conductive material in form of particles or one or more layers or layer structures may improve the electrostatic discharge properties of the package as a whole.

In an embodiment, the encapsulant comprises a mold compound. For example, such a mold compound may comprise an epoxy resin, filler particles, optionally additives, and optionally a limited amount of electrically conductive particles, such as carbon black.

In an embodiment, the further encapsulant comprises a mold compound, in particular comprising carbon black as the electrically conductive material (see for example FIG. 1). For example, such a further mold compound may comprise a further epoxy resin, further filler particles, optionally further additives, and a certain amount of electrically conductive particles, such as carbon black. For instance, the further encapsulant may be formed by overmolding the aforementioned encapsulant.

In another embodiment, the further encapsulant is a further carrier (see for instance FIG. 3). In particular, the further encapsulant may comprise a ceramic sheet (which may be thermally conductive and electrically insulating, for instance aluminum oxide or aluminum nitride) covered on both opposing main surfaces thereof with a metal layer (for instance copper or aluminum layers) as the electrically conductive material. When such a further carrier is arranged on an exterior surface of the aforementioned encapsulant, it may function as a further encapsulant.

In an embodiment, each of the carrier and the further carrier is exposed beyond the encapsulant for removing heat, generated by the electronic component, by double-sided cooling. Hence, heat created by the electronic component (for instance a power semiconductor chip) may be dissipated from the package via both exposed carriers through two opposing sides, and thus highly efficiently. For this purpose, the at least one electronic component may be preferably thermally coupled with both carriers. For instance, the electronic component may be mounted on one carrier and may be thermally connected with the other carrier by a thermally conductive spacer body in between.

In an embodiment, the encapsulant forms an inner core and the further encapsulant forms an outer shell on at least part of the inner core. With such a core-shell configuration of the two-encapsulant (wherein also more than two encapsulants may be foreseen) system, the technical functions of the inner encapsulant and of the outer encapsulant may be combined in a structurally advantageous fashion.

In an embodiment, the further encapsulant is configured to provide better protection against electrostatic discharge (ESD) than the encapsulant. More specifically, ESD protection may be predominantly or entirely provided by the exterior further encapsulant which may have a higher amount of electrically conductive particles than the interior encapsulant.

In an embodiment, the further encapsulant is configured to enable better laser marking thereon and/or therein than the encapsulant. Laser marking of a package may be strongly enhanced by carbon black which can be characteristically modified by laser treatment in a surface region of the further encapsulant.

In an embodiment, the encapsulant is in direct physical contact and the further encapsulant is not in direct physical contact with the electronic component and/or the carrier. By depleting carbon black in the encapsulant being in direct contact in particular with the electronic component, the electronic component may be properly protected against corrosion. At the same time, a large or larger amount of carbon black in the further encapsulant does not deteriorate the corrosion protection of the electronic component, since the latter is not in direct physical contact with the further encapsulant. Corresponding considerations apply to the other advantages of larger and smaller amounts of electrically conductive particles, such as carbon black particles, as mentioned above.

In an embodiment, the further encapsulant defines part of an exterior outline of the package. Hence, the further encapsulant can be arranged remote from the electronic component which may further improve the electric reliability. At the same time, the further encapsulant extending up to the exterior surface of the package may be used for laser marking purposes and ESD protection.

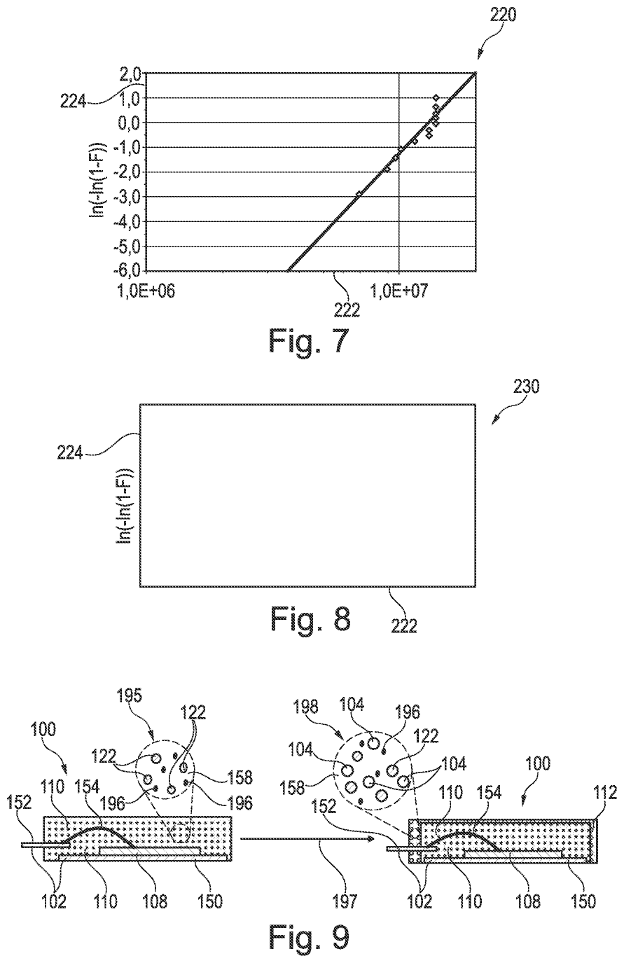

In an embodiment, the encapsulant is configured for providing a higher time-dependent dielectric breakdown (TDDB) safety than the further encapsulant. Surprisingly, this improvement of the electric reliability can be achieved by reducing the amount of carbon black in the encapsulant (see FIG. 7 and FIG. 8).

In an embodiment, the encapsulant is configured for providing a higher high-voltage safety than the further encapsulant. Surprisingly, this improvement of the electric reliability can be achieved by reducing the amount of carbon black in the encapsulant (see FIG. 6).

In an embodiment, the electrically conductive particles comprise at least one of carbon black, titanium oxide, and crystalline petroleum coke. The mentioned particles provide a certain electric conductivity for removing charge carriers from the package. However, the electric conductivity of the mentioned materials is not excessively high. The risk of undesired conduction of current of significant amount along parasitic paths may thus be reduced. Therefore, the mentioned materials are highly appropriate as electrically conductive particles in one or both of the encapsulants.

In an embodiment, the electrically conductive particles have an electric conductivity of at least 0.01 S/cm, in particular at least 0.1 S/cm, more particularly in a range from 0.05 S/cm to 500 S/cm, for instance in a range from 0.1 S/cm to 100 S/cm. The electric conductivity of the electrically conductive particles may be below a metallic conductivity (for instance of materials such as copper or aluminum), which may be preferred for the function of the electrically conductive particles in the package.

In an embodiment, the encapsulant is free of a low stress additive (such as rubber or silicone particles). As shown and described in FIG. 6, omitting low stress additives may lead surprisingly to an advantageous dielectric strength behavior.

In an embodiment, the encapsulant comprises uncoated filler particles. Again referring to FIG. 6, the implementation of filler particles (for instance for enhancing thermal conductivity) in the encapsulant which do not have a coating (but are made preferably of homogeneous material) may lead to an improvement of the dielectric strength behavior.

In an embodiment, part of the carrier is exposed beyond the encapsulant and beyond the further encapsulant. This may promote the heat removal capability of the package via the carrier, which may carry the main heat source of the package, i.e. the electronic component.

In an embodiment, the encapsulant comprises an electrostatic dissipative material. For example, said electrostatic dissipative material may comprise electrically conductive particles bound to segments of an epoxy backbone of material of the encapsulant. Additionally or alternatively, said electrostatic dissipative material may comprise short electrically conductive moieties reacted with epoxy material of the encapsulant.

In an embodiment, the method comprises forming the further encapsulant by molding, in particular overmolding, on at least part of the encapsulant. Forming two different mold-type encapsulants with the above-described properties on each other allows to obtain a simple manufacturing process and a high electric reliability of the formed package.

In another embodiment, the method comprises forming the further encapsulant by coating at least part of the encapsulant. For example, such a coating process may be accomplished by painting, spraying, depositing, and/or dipping. Also such a manufacturing process is simple and allows to adjust the properties of encapsulant and further encapsulant individually with a high freedom of design.

In yet another embodiment, the method comprises forming the further encapsulant by modifying a surface portion of the encapsulant. Thus, the further encapsulant may be manufactured as a former exterior part of the other encapsulant, which can be (for instance chemically) modified for adjusting in particular the concentration of electrically conductive particles therein, preferably carbon black.

In an embodiment, modifying the surface portion of the encapsulant is carried out by at least one of ultraviolet radiation-triggered carbonization, treating by a laser, treating by an electron beam, phase separation based on hydrophobicity, flaming, burning, and oxidizing. For example, the exterior surface of the encapsulant may be irradiated by ultraviolet radiation which may carbonize material of the former encapsulant. As a result, electrically conductive particles, such as carbon black, may be formed selectively in a surface portion of the former encapsulant, which will then be the further encapsulant.

In an embodiment, the package comprises at least one further electronic component mounted on the carrier and/or on another carrier. In particular, a plurality of electronic components may be mounted side-by-side and/or on top of each other on the same carrier and/or on different carriers of the same package. Said electronic components may be interconnected with each other or may operate independently from each other.

In an embodiment, the package is configured as power package. A power package may be a package comprising at least one power chip as encapsulated electronic component. Thus, the package may be configured as power module, for instance molded power module such as a semiconductor power package. For instance, an exemplary embodiment of the package may be an intelligent power module (IPM). Another exemplary embodiment of the package is a dual inline package (DIP).

Correspondingly, the electronic component may be configured as a power semiconductor chip. Thus, the electronic component (such as a semiconductor chip) may be used for power applications for instance in the automotive field and may for example have at least one integrated insulated-gate bipolar transistor (IGBT) and/or at least one transistor of another type (such as a MOSFET, a JFET, a HEMT, etc.) and/or at least one integrated diode. Such integrated circuit elements may be manufactured for instance in silicon technology or based on wide-bandgap semiconductors (such as silicon carbide, gallium nitride). A semiconductor power chip may comprise one or more field effect transistors, diodes, inverter circuits, half-bridges, full-bridges, drivers, logic circuits, further devices, etc. Advantages of exemplary embodiments concerning electric isolation and thermal dissipation are particularly pronounced for power dies.

In an embodiment, the carrier comprises a leadframe-type die pad. A leadframe may be a metal structure inside the package that carries signals from the electronic component to the outside, and/or in opposite direction. The leadframe may comprise a central die pad, on which the electronic component is placed, surrounded by leads, i.e. metal conductors leading away from the electronic component to the electronic delivery of the package, and/or in opposite direction.

In an embodiment, the package comprises a heat sink mounted on a portion of the encapsulant facing the carrier or a carrier-type further encapsulant. Such a heat sink may be a heat dissipation body, which may be made of a highly thermally conductive material such as copper or aluminum which may be attached to the encapsulant surface being arranged closest to the back side of the carrier. For instance, such a heat sink may have a base body being directly connected to the surface of the package and may have a plurality of cooling fins extending from the base body and in parallel to each another so as to remove the heat towards the environment.

In an embodiment, the package comprises an electrically conductive connection element electrically coupling the electronic component with the carrier and/or with at least one lead. Such an electrically conductive connection element may be a clip, a bond wire or a bond ribbon. A clip may be a curved electrically conductive body accomplishing an electric connection with a high connection area to an upper main surface of a respective electronic component. Additionally or alternatively to such a clip, it is also possible to implement one or more other electrically conductive connection elements in the package, for instance a bond wire and/or a bond ribbon connecting the electronic component with the carrier and/or a lead or connecting different pads of an electronic component.

In an embodiment, the package is configured as one of the group consisting of a leadframe connected power module, a Control integrated power system (CIPOS) package, a Transistor Outline (TO) package, a Quad Flat No Leads Package (QFN) package, a Small Outline (SO) package, a Small Outline Transistor (SOT) package, and a Thin Small Outline Package (TSOP) package. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts and appears externally as a conventional package, which is highly user-convenient.

As substrate or wafer forming the basis of the electronic components, a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Epoxy molding compounds are conventionally used for the encapsulation of semiconductor components. These polymer composites are used to give mechanical stability to the package (for example hold leads) as well as protecting the semiconductor component from environmental influences. In order to fulfill different requirements for the encapsulation material, various additives are used. One of the additives typically used is a coloring agent, which may be electrically conductive. These coloring agents (typically carbon black) are used to ensure that the mold compound has a stable, uniform color (for example black in case of carbon black). In addition, carbon black is used as an ESD (electrostatic discharge) protection agent to reduce the risk of ESD for the package in view of its intrinsic electric conductivity.

However, in recent studies, the inventors have found out that an excessive amount of carbon black has a disadvantage when it comes to partial discharge measurements as well as time dependent dielectric breakdown measurements. Here, an excessive amount of carbon black may cause a reduced breakdown voltage (BDV) in consecutive BDV measurements. Without wishing to be bound to a specific theory, it is presently believed that the reason for this may be probably that during the electrical breakdown, the carbon black can form a conductive path which then reduces the BDV in consecutive measurements. Descriptively speaking, this phenomenon may be denoted as electrical treeing. Having an epoxy mold compound material without carbon black or with a sufficiently low amount of carbon black in an area where high voltage is present in the package (for example close to a die-type electronic component) may be therefore beneficial.

According to an exemplary embodiment, a package may be provided with a carrier (such as a leadframe structure or a ceramic plate with metal layers on opposing main surfaces thereof) on which one or more electronic components (for example a semiconductor chip) is assembled (for instance by soldering or sintering). An interior encapsulant surrounding at least part of electronic component and carrier may be provided with a low amount of not more than 0.1 weight percent electrically conductive particles. Furthermore, an exterior encapsulant with a higher amount (for example more than 0.1 weight percent or more than 0.2 weight percent, but for example less than 1%, in relation to an entire weight of the exterior encapsulant) of electrically conductive material (in particular particles) may surround at least part of the first encapsulant. The described combination of an interior and an exterior encapsulant with different electrically conductive particle concentrations may result in a high electric reliability. The interior first encapsulant with low amount of electrically conductive particles (for instance carbon black particles) may ensure a high breakdown voltage and a pronounced long-term high voltage stability. Simultaneously, the partial or complete depletion of electrically conductive particles in the interior first encapsulant may suppress corrosion in an interior of the package and may enhance adhesion inside the package. In addition, the exterior encapsulant with larger amount of electrically conductive material (for example carbon black particles) may enhance electrostatic discharge (ESD) protection of the package without negative impact on the encapsulated electronic component.

According to another exemplary embodiment, a package is provided which comprises a carrier, an electronic component mounted on the carrier, and an encapsulant at least partially encapsulating the electronic component and the carrier, wherein the encapsulant is free of coloring agent (in particular is free of carbon black). Such a package may have an encapsulant which does not have electrically conductive particles at all. This may lead to an advantageous electric reliability. In such an embodiment, the encapsulant may or may not be surrounded by a further encapsulant.

In particular, different embodiments may relate to a package without carbon black, or a package core without carbon black or at least without an excessive amount of carbon black and/or other electrically conductive particles.

One embodiment may provide a package with a molding compound without coloring agent which may contribute to improve the time dependent dielectric breakdown (TDDB) performance of the package. TDDB is an important test for various packages, such as gate drivers or opto-couplers. Additionally, discrete devices are striving for higher voltage classes, where similar effects may be important. In order to ensure that the removal or reduction of carbon black and/or other conductive particles from an interior encapsulant of a package does not compromise the reliability of the package, the package may be formed with an inner core mold compound material without carbon black or with a sufficiently low amount of carbon black. Said inner core mold compound material may be surrounded by an external shell with carbon black or with a larger amount of carbon black or other electrically conductive particles.

In an embodiment, a semiconductor package is provided which comprises an inner encapsulant (such as an inner core structure of molding compound) with limited amount or even without electrically conductive coloring agent to improve the time-dependent dielectric breakdown (TDDB) performance of the package. Thus, a semiconductor package may be provided which has an inner core structure of molding compound around a die-type electronic component and a second outer structure. For example, the molding compound of the inner structure does not comprise an electrically conductive coloring agent (such as carbon black) or electrically conductive particles of a limited amount of not more than 0.1 weight percent in relation to the entire weight of the molding compound of the inner structure. Furthermore, the outer structure may be made of a molding compound with or with a larger amount of coloring agent (like carbon black or titanium oxide), or may be made of another material than a molding compound (for example formed by dipping or coating material, coloring dip, etc.). Advantageously, the outer structure may provide efficient ESD protection and laser marking ability of the package.

In one embodiment, a semiconductor package is provided which comprises a molding compound without electrically conductive particles, carbon black or coloring agent. In such an embodiment, the whole electronic component may be encapsulated with a mold compound being free of carbon black.

In another embodiment, a semiconductor package is provided which comprises an inner core structure of a mold compound without carbon black, or with a limited amount of carbon black or other electrically conductive particles, around a (for example die-type) electronic component. This may provide a pronounced electrical reliability where high-voltage is applied during operation of the package. In addition, a second outer structure may be formed.

The inner core structure may or may not contain electrostatic dissipative material. Electrostatic dissipative materials may be in form of conductive organic or inorganic particles covalently or non-covalently (for example with x-x interaction) bound to segments of an epoxy backbone to create a spatial distribution and prevent formation of a long conductive path by particle agglomeration. Electrostatic dissipative materials may also comprise short conducting moieties (CP) reacted with epoxy of mold compound, forming CP-co-epoxy copolymer or CP dangling as a side chain of an epoxy backbone.

The second outer structure may be provided to offer different properties to the inner shell with regard to the color (for example black surrounding) and/or the ESD protection of the package. In that case, the inner core structure may offer a TDDB safe and/or high-voltage safe material, while the outer shell may offer a compound that can be used for laser marking and for ESD protection.

In the following, different examples for the latter mentioned embodiment will be explained. For example, the inner core may be made of epoxy mold compound without coloring agent, or with a limited amount of coloring agent or other electrically conductive particles. For the outer structure, there are different possibilities:
The outer structure may be made of the same or another epoxy mold compound as the inner structure, but may additionally include carbon black, or carbon black or other electrically conductive particles of a higher amount than the inner structure.
The outer structure may be embodied as a sealing layer (for instance made of paint, etc.).
The outer structure may be originally made of the same material as the inner core structure, wherein its properties may be changed by an additional treatment after molding. Such an additional treatment can for instance be embodied as treatment by a high power UV (ultraviolet) lamp which is carbonizing the outer structure. The additional treatment may also be a laser treatment influencing the outer structure, for example triggering an oxidation process influencing the outer layer.

Overmolding technologies may be implemented in various embodiments as well.

While carbon black may be advantageous in an encapsulant for defining the package color (in particular for rendering the package suitable for laser marking) and ESD protection, it may also have a negative impact on TDDB behavior. Hence, removal of carbon black or limiting its amount in a package area where a high electrical field is present during operation may be beneficial, i.e. in the inner encapsulant. However, without carbon black, laser marking on an exterior surface of the package may be difficult and ESD protection may be deteriorated. In order to ensure the ability of laser marking and to provide a reliable ESD protection, the exterior further encapsulant may comprise carbon black or other electrically conductive material (in particular particles).

Therefore, a gist of an exemplary embodiment may be to provide a semiconductor package in which an epoxy mold compound without carbon black is used in the sensitive, high voltage area of the package (in particular in an inner region), which is covered by an external layer that offers ESD protection and laser marking possibility (for example an external shell of epoxy mold compound with carbon black).

There are different possibilities as to how to produce a double structure of an interior encapsulant (for instance being free of carbon black or other electrically conductive particles, or having a limited amount of not more than 0.1 weight percent thereof) and an exterior encapsulant thereon (for instance comprising carbon black or other electrically conductive particles, or having a larger amount of carbon black or other electrically conductive particles than the interior encapsulant).

For example, the exterior encapsulant may be formed on the interior encapsulant by an additional processing stage after molding. For instance, this may be accomplished by dipping or spray coating. More specifically, molding material of the interior encapsulant (for example without carbon black) may be subjected to heat curing. Thereafter, a thin film of material of exterior encapsulant (for instance with carbon black) may be formed by dipping or spray coating. Thereafter, post processing may be optionally executed.

It is also possible to form the exterior encapsulant on the interior encapsulant by an additional processing stage after molding which involves treatment by an electron beam. After having formed molding material of the interior encapsulant (for example without carbon black), the obtained structure may be subjected to heat curing. Thereafter, the exterior surface may be irradiated with an electron beam to form a thin amorphous carbon-containing film on the surface. Thereafter, post processing may be optionally executed.

In yet another embodiment, the exterior encapsulant may be formed on the interior encapsulant by phase separation based on hydrophobicity. In this context, it may be possible to form, by molding, an epoxy mold compound containing a hydrophobic colorant (for example PDMS (Polydimethylsiloxane)-grafted TiO₂, hydrophobic carbon black). Thereafter, a heat curing process may be executed. For instance, epoxy and hydrophobic colorant can phase separate at elevated temperature. The hydrophobic colorant (for example PDMS-grafted TiO₂) may migrate to the surface when epoxy is still molten. Thereafter, post processing may be optionally executed.

In the following table, the electrical conductivity of different materials, which may form part of a package, is indicated:

| | Electrical conductivity |
|---|---|
| Material | (S/cm) |
| Epoxy | ~10⁻⁹ |
| SiO₂ | ~10⁻¹² |
| TiO₂ | <10-10 |
| Carbon black | 0.1-10² |

For instance, carbon black and/or titanium oxide may be used as electrically conductive particles of material an encapsulant of the package. A highly crystalline petroleum coke produced (for example exclusively) from fluid catalytic cracking decant oil or coal tar pitch may also be used as the above-described particles of the package.

In an embodiment, it is possible that the exterior encapsulant (which may comprise for example carbon black) is manufactured prior to the interior encapsulant (which may be free of carbon black). For example, a cavity package may be manufactured with the exterior encapsulant as exterior shell delimiting an interior hollow space. Said hollow space may then be filled with the interior encapsulant.

For example in an embodiment in which one or more Direct Copper Bonding (DCB) substrates form part of a package (for instance as carrier and/or further encapsulant), molding for forming the interior encapsulant may be executed after die assembly, spacer soldering, etc.

FIG. 1 illustrates a cross-sectional view of a package 100 according to an exemplary embodiment.

The illustrated package 100 comprises a carrier 102, which may be for example a leadframe structure. Such a leadframe structure may be a patterned metallic plate forming a base 150 for an electronic component 108 described in the following. Said base 150 of the carrier 102 may be a die pad. Furthermore, the leadframe structure-type carrier 102 may also comprise one or more lead structures 152.

As already mentioned, package 100 comprises an electronic component 108 which is mounted on the carrier 102, more specifically on base 150 thereof. For example, electronic component 100 may be a semiconductor die, for instance a semiconductor power chip. Electronic component 108 may be mounted on carrier 102 for example by soldering, sintering or gluing. Although not shown in detail in FIG. 1, electronic component 108 may comprise one or more electrically conductive pads on one or both opposing main surfaces thereof. For instance, a pad on a top may surface of the electronic component 108 may be electrically connected with lead structure 152 by an electrically conductive connection structure 154, such as a bond wire (or alternatively a clip, not shown).

Furthermore, package 100 comprises an encapsulant 110, which is here embodied as a mold compound. Preferably, encapsulant 110 may comprise not more than 0.1 weight percent (preferably not more than 0.05 weight percent), in relation to an entire weight of the encapsulant 110, of electrically conductive particles 104, as shown in a detail 156. More specifically, the encapsulant 110 may comprise electrically conductive particles 104 in the form of carbon black, in a range from 0.025 weight percent to 0.05 weight percent in relation to the entire weight of the encapsulant 110. The already mentioned detail 156 illustrates that only a limited amount of electrically conductive particles 104, such as carbon black particles, are embedded in a matrix 158 of encapsulant 110. Matrix 158 may comprise epoxy resin, filler particles (for instance aluminum nitride particles for enhancing electric conductivity), additives, etc. As shown, the encapsulant 110 encapsulates the electronic component 108 and part of the carrier 102.

Moreover, a further encapsulant 112 is provided which covers an exterior surface of part of the encapsulant 110. For instance, further encapsulant 112 may be a further mold compound. For example, further encapsulant 112 may be formed by overmolding encapsulant 110. Referring to a further detail 160, further encapsulant 112 may have a larger amount of electrically conductive material 106 than the encapsulant 110. In the embodiment of FIG. 1, said electrically conductive material 106 is embodied as further electrically conductive particles, for instance as well of carbon black. For example, the amount of electrically conductive particles of further encapsulant 112 may be larger than 0.1 weight percent (preferably at least 0.15 weight percent), in relation to the entire weight of the further encapsulant 112. Detail 160 illustrates that a significant amount of electrically conductive particles, such as carbon black particles, are embedded in a further matrix 162 of further encapsulant 112. Matrix 162 may comprise epoxy resin, filler particles (for instance aluminum nitride particles for enhancing thermal conductivity), additives, etc.

Epoxy resin, filler particles and/or additives of encapsulants 110, 112 may be the same or may be different and may be selected in accordance with the requirements of a certain application.

Advantageously, inner or core encapsulant 110 has a limited amount (or even is entirely free) of electrically conductive particles 104. This may lead to an increased breakdown voltage, an improved long-term high voltage stability, reduced corrosion and enhanced adhesion in an interior of package 100.

Simultaneously, exterior or shell encapsulant 112 has a larger amount of electrically conductive particles, such as carbon black, than core encapsulant 110. This may provide ESD protection to package 100 and may render an exterior surface of package 100 suitable for laser marking thereon.

The described combinatory configuration of encapsulants 110, 112 may allow to obtain package 100 which may benefit from the above-mentioned advantages in combination.

Still referring to FIG. 1, the encapsulant 110 forms an inner core on electronic component 108, whereas the further encapsulant 112 forms an outer shell on part of the inner core. More specifically, the encapsulant 110 is in direct physical contact with the electronic component 108 and with the carrier 102, whereas the further encapsulant 112 is not in direct physical contact with the electronic component 108. Furthermore, the further encapsulant 112 defines a significant part of an exterior outline of the package 100. As shown, part of the carrier 102 is exposed beyond the encapsulant 110 and beyond the further encapsulant 112. The exposed surface of the carrier 102 may be used for establishing an electric contact with an electronic periphery and/or for removing heat generated in particular by electronic component 108 during operation of package 100.

The inner core material of encapsulant 110 may be made for example of epoxy mold compound with limited amount of carbon black or even without carbon black.

The outer shell of package 100 provided by further encapsulant 112 may provide ESD protection and laser marking ability. Said outer shell can be made of various materials, for example mold compound with carbon black (so that encapsulant 110 and further encapsulant 112 may be formed by double molding). Other materials for further encapsulant 112 are a dipping material, a coating material, a coloring dip, etc.

For example, further encapsulant 112 may be created by a post treatment of an exterior portion of encapsulant 112 to change an outer surface (for instance in a way to improve ESD protection and/or to enable laser marking on an exterior surface). Such a post treatment may be for example executed during tin plating. Post treatment for surface modification may be accomplished also by a UV lamp, a UV flash, laser treatment, flaming, burning and/or etching.

In particular for forming further encapsulant 112 as an epoxy mold compound with carbon black, said additional mold compound may be molded onto encapsulant 110 after a post treatment. By two-stage molding, it may be possible to form an outer encapsulant shell on an inner encapsulant core with different properties. For example, further encapsulant 112 may be formed with higher electrical conductivity than encapsulant 110 for enhancing ESD protection. Further encapsulant 112 may also be configured for enabling laser marking directly thereon.

FIG. 2 illustrates a flowchart 200 of a method of manufacturing a package 100 according to an exemplary embodiment. The reference signs used for the following description of said manufacturing method relate to the embodiment of FIG. 1.

Referring to a block 202, the method comprises mounting an electronic component 108 on a carrier 102.

Referring to a block 204, the method comprises at least partially encapsulating the electronic component 108 and the carrier 102 by an encapsulant 110 which comprises not more than 0.1 weight percent, in relation to an entire weight of the encapsulant 110, of electrically conductive particles 104.

Referring to a block 206, the method comprises forming a further encapsulant 112 at an exterior surface of at least part of the encapsulant 110, wherein the further encapsulant 112 has a larger amount of electrically conductive material 106 than the encapsulant 110.

FIG. 3 illustrates a cross-sectional view of a package 100 according to another exemplary embodiment.

The embodiment according to FIG. 3 differs from the embodiment according to FIG. 1 in that, according to FIG. 3, the encapsulant 110 is free of electrically conductive particles 104 (see detail 164). A further difference between the embodiment of FIG. 3 and the embodiment of FIG. 1 is that, according to FIG. 3, carrier 102 comprises a ceramic sheet 166 (for instance made of aluminum oxide or aluminum nitride) which is covered on each opposing main surface thereof by a respective metal layer 168, 170 (for instance a copper layer or an aluminum layer). For example, carrier 102 according to FIG. 3 may be a DCB substrate or a DAB substrate. The ceramic sheet 166 is electrically insulating and thermally conductive. The metal layers 168, 170 are electrically conductive and thermally conductive. Any of the metal layers 168, 170 may be continuous or patterned. Hence, carrier 102 may be highly thermally conductive and may be capable of removing heat generated by electronic component 108 during operation of package 100 towards a bottom side.

Yet another difference between the embodiment of FIG. 3 and the embodiment of FIG. 1 is that the embodiment of FIG. 3 does not comprise a second mold-type encapsulant. In contrast to this, the further encapsulant 112 of FIG. 3, forming part of an exterior surface of package 100 and covering part of an exterior surface of encapsulant 110, is embodied as a further ceramic sheet 116 (for instance made of aluminum oxide or aluminum nitride) which is covered on each opposing main surface thereof by a respective further metal layer 118, 120 (for instance a copper layer or an aluminum layer. For example, further encapsulant 112 according to FIG. 3 may be a further DCB substrate or a further DAB substrate. Hence, the further encapsulant 112 of FIG. 3 is embodied as a further carrier. The further ceramic sheet 116 is electrically insulating and thermally conductive. The further metal layers 118, 120 are electrically conductive and thermally conductive. Any of the metal layers 118, 120 may be continuous or patterned. Hence, further encapsulant 112 according to FIG. 3 may be highly thermally conductive and may be capable of removing heat generated by electronic component 108 during operation of package 100 towards a top side.

According to FIG. 3, each of the carrier 102 and the further carrier is exposed beyond the encapsulant 110 for removing heat, generated by the electronic component 108, by double-sided cooling. As can be taken from the foregoing, the configuration according to FIG. 3 provides a package 100 configured for double-sided cooling, since heat created by electronic component 108 can be removed through carrier 102 to the bottom side and through further encapsulant 112 to the top side of the package 100. Although not shown in FIG. 3, the top main surface of the electronic component 108 may be optionally coupled to the bottom side of the further encapsulant 112 by a thermally conductive spacer (such as a metal block or a ceramic block).

Still referring to FIG. 3, the inner core material of encapsulant 110 may be epoxy mold compound without carbon black. The further encapsulant 112 forming an outer shell of the package 100 is here embodied as a DCB covering the inner core on top. A further DCB is provided as carrier 102 at the bottom side. Although not shown, one or more electronic components 108 (such as electronic chips) can be assembled on both sides of the DCBs in the interior of package 100, i.e. on the top side of carrier 102 and/or on the bottom side of further encapsulant 112. As an alternative to a DCB, it is also possible to use a DAB or an AMB.

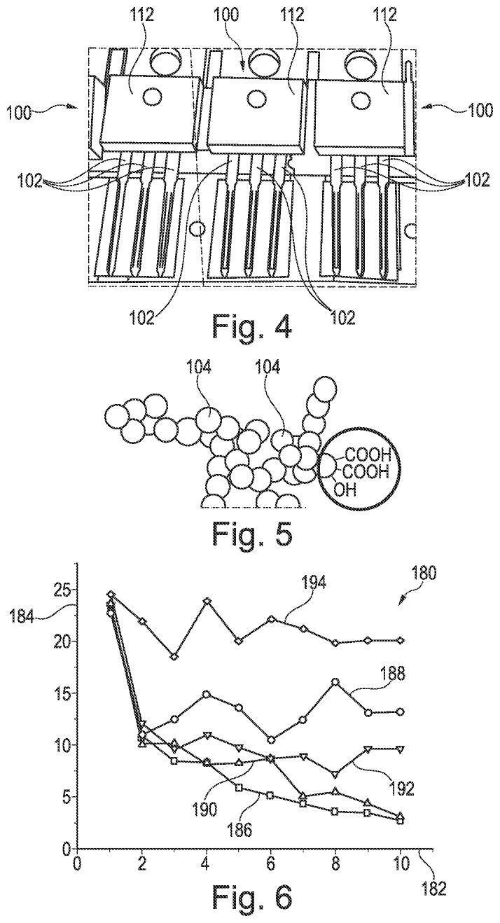

FIG. 4 illustrates a three-dimensional view of a preform of a package 100 according to another exemplary embodiment. More specifically, FIG. 3 shows a leadframe (which may be a punched metal plate, for example made of copper) on which one or more electronic chips may be mounted and encapsulated. A corresponding exterior encapsulant 112 may define a package color, may enable laser writability, and may enhance ESD protection. Without carbon black, an encapsulant may have a greyish color.

FIG. 5 illustrates a constituent of a package 100 according to another exemplary embodiment. More specifically, FIG. 5 shows a plurality of electrically conductive particles 104 (in particular made of carbon black). When the amount of carbon black is excessively large, the carbon black-type electrically conductive particles 108 may agglomerate and may form continuous electrically conductive pathways. This may reduce the breakdown voltage. Consequently, the amount of electrically conductive particles 108, in particular in core-type interior encapsulant 110, should not be too high. Hence, carbon black can influence the interaction to the surface. By agglomeration, a weakening of the electric reliability may occur. Such undesired phenomena may be prevented by reducing the amount of electrically conductive particles 104 in core-type interior encapsulant 110.

FIG. 6 to FIG. 8 illustrate diagrams showing effects of exemplary embodiments over conventional approaches.

Referring to FIG. 6, a diagram 180 is shown which has an abscissa 182 and an ordinate 184. Along the abscissa 182, a number of consecutive measurements on a tested sample is plotted for different configurations of an encapsulant 110. Along the ordinate 184 the dielectric strength is plotted (in kV/mm). FIG. 6 illustrates the influence of coloring agents, such as carbon black, on repeated breakdown measurements.

A curve 186 shows a scenario corresponding to a conventional mold-type encapsulant with a significant amount of carbon black. As shown, the electric breakdown voltage becomes low after a certain amount of measurements.

A curve 188 shows a scenario corresponding to a mold-type encapsulant without low stress additives. Curve 188 shows an improvement as compared with curve 186. Consequently, an exemplary embodiment provides an encapsulant 110 being free of a low stress additive (such as rubber and/or silicone particles).

A curve 190 shows a scenario corresponding to a mold-type encapsulant with non-coated filler particles. Curve 190 shows an improvement as compared with curve 186. Consequently, an exemplary embodiment provides an encapsulant 110 having filler particles without a coating (see reference sign 122 in FIG. 9).

A curve 192 shows a scenario corresponding to a mold-type encapsulant with titanium oxide as colouring agent. Titanium oxide shows a slight improvement over carbon black (curve 186).

A curve 194 shows a scenario corresponding to a mold-type encapsulant without electrically conductive particles, in particular without carbon black. As shown, curve 194 stabilizes at a high value of the breakdown voltage after many measurements. Hence, the encapsulant configuration according to curve 194 in accordance with an embodiment is highly advantageous.

Summarizing, configuring an interior encapsulant 110 of a package 100 of an exemplary embodiment without carbon black (or without an excessive amount of carbon black) may provide the following advantages:
Reduce the CTI (comparative tracking index). Descriptively speaking, the CTI value (in Volts) may be a measure of the electric breakdown voltage of an insulator. To put it shortly, a package having a larger breakdown voltage can be used or operated at a higher voltage than a package having a smaller breakdown voltage. More specifically, an analysis shows an improvement on CTI when mold compounds contain less carbon black concentration. This can be derived from the following table:

| | | | Carbon black quantity (relative to | | | |
|---|---|---|---|---|---|---|
| | | | a reference formulation) | | | |
| | | | 0% | 50% | 75% | 100% |
| CTI result | 600 V | Drops | 91 | 62 | 58 | 55 |
| (average | 700 V | Drops | 63 | 46 | 26 | <10 |
| drops) | 800 V | Drops | 62 | 27 | <10 | — |

Improve the BDV (breakdown voltage), see FIG. 6.
Increase adhesion on copper

Hence, removal or reduction of carbon black from encapsulant 110 may provide several advantages.

FIG. 7 and FIG. 8 shows the influence of carbon black on TDDB. Thus, FIG. 7 and FIG. 8 indicate a result of a TDDB study.

Referring to FIG. 7, a diagram 220 is shown which has an abscissa 222 and an ordinate 224. Along the abscissa 222, a time to breakdown (in seconds) at 25° C. is plotted. Along the ordinate 224, a parameter indicative of TDDB is plotted. FIG. 7 relates to a stress voltage of 3500 V. Each dot or data point in diagram 220 indicates a package which has failed due to electric breakdown. FIG. 7 shows a scenario corresponding to a conventional mold-type encapsulant with a significant amount of carbon black. Thus, FIG. 7 relates to a reference epoxy mold compound used in a DSO-type package.

Referring to FIG. 8, a diagram 230 is shown which corresponds to diagram 220, but relates to an epoxy mold compound formulation without carbon black. As shown in FIG. 8, not a single failure occurred over a temporal range of about 6 months. Hence, avoiding an excessive amount of electrically conductive particles such as carbon black in an encapsulant 110 may significantly improve the TDDB behaviour.

FIG. 9 illustrates structures obtained during manufacturing a package 100 according to an exemplary embodiment.

As shown on the left-hand side of FIG. 9, a package 100 is shown which can be obtained by mounting an electronic component 108 on a carrier 102. After electrically connecting electronic component 108 with lead structure 152 by an electrically conductive connection element 154, carrier 102 and electronic component 108 may be partially encapsulated by encapsulant 110. As shown in detail 195, encapsulant 110 of FIG. 9 comprises above-described matrix 158, additives 196 and uncoated filler particles 122 (the latter may improve electric reliability, as has been explained above referring to FIG. 6). However, encapsulant 110 of FIG. 9 does not comprise carbon black.

As indicated by reference sign 197, the structure shown on the left side of FIG. 9 may then be subjected to a further manufacturing stage for forming further encapsulant 112 as a modified exterior surface of part of the encapsulant 110. As shown in detail 198, the further encapsulant 112 has—in addition to the constituents of encapsulant 110—electrically conductive particles 104 in the form of carbon black.

In the shown embodiment, the further encapsulant 112 may be formed based on exterior material of encapsulant 110 by modifying a surface portion of said encapsulant 110. More specifically, by ultraviolet (UV) radiation-triggered carbonization of exposed material of encapsulant 110, carbon black particles may be formed in further encapsulant 112.

Corresponding results may be obtained alternatively by treating an exterior portion of encapsulant 110 by a laser, by an electron beam, by phase separation based on hydrophobicity, by flaming, by burning, and/or by oxidizing.

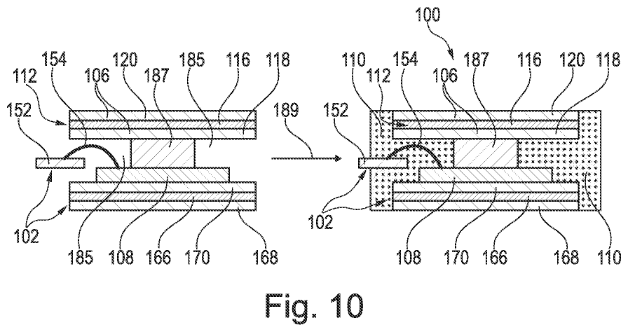

FIG. 10 illustrates structures obtained during manufacturing a package 100 according to another exemplary embodiment. According to this embodiment, the further encapsulant 112 is formed before forming the encapsulant 110.

In FIG. 10, the DCB-type exterior further encapsulant 112 (which may comprise a large amount of electrically conductive material 106 in form of metal layers 118, 120) is manufactured prior to the interior encapsulant 110 (which may be free of carbon black or which may comprise a limited amount of carbon black). As shown on the left hand side, a preform with a cavity or void volume 185 may be manufactured.

On the left hand side, electronic component 108 mounted on carrier 102 and being electrically connected with lead structure 152 by electrically conductive connection structure 154 is provided with a thermally conductive spacer 187 mounted on top of electronic component 108. Further encapsulant 112, here a DCB substrate, is mounted on top of spacer 187.

Thereafter (see arrow 189), as shown on the right hand side of FIG. 10, encapsulant 110 is formed by filling void volume 185 by a mold compound, i.e. by molding.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
a carrier;
an electronic component mounted on the carrier;
an encapsulant comprising not more than 0.1 weight percent, in relation to an entire weight of the encapsulant, of electrically conductive particles, wherein the encapsulant at least partially encapsulates the electronic component and the carrier; and
a further encapsulant covering an exterior surface of at least part of the encapsulant and having a larger amount of electrically conductive material than the encapsulant.

2. The package according to claim 1, comprising one of the following features:
wherein the encapsulant comprises electrically conductive particles, for example carbon black, in a range from 0.025 weight percent to 0.05 weight percent in relation to the entire weight of the encapsulant;
wherein the encapsulant is free of electrically conductive particles.

3. The package according to claim 1, wherein the encapsulant comprises not more than 0.05 weight percent, in relation to the entire weight of the encapsulant, of carbon black as the electrically conductive particles.

4. The package according to claim 1, wherein the electrically conductive material of the further encapsulant comprises electrically conductive particles, for example carbon black, or comprises at least one metal layer.

5. The package according to claim 1, wherein the encapsulant comprises a mold compound.

6. The package according to claim 1, wherein the further encapsulant comprises a mold compound, for example comprising carbon black as the electrically conductive material.

7. The package according to claim 1, wherein the further encapsulant is a further carrier, in particular comprising a ceramic sheet covered on both opposing main surfaces thereof with a metal layer as the electrically conductive material.

8. The package according to claim 7, wherein each of the carrier and the further carrier is exposed beyond the encapsulant for removing heat, generated by the electronic component, by double-sided cooling.

9. The package according to claim 1, wherein the encapsulant forms an inner core and the further encapsulant forms an outer shell on at least part of the inner core.

10. The package according to claim 1, wherein the further encapsulant is configured to provide better protection against electrostatic discharge than the encapsulant.

11. The package according to claim 1, wherein the further encapsulant is configured to enable better laser marking thereon and/or therein than the encapsulant.

12. The package according to claim 1, wherein the encapsulant is in direct physical contact and the further encapsulant is not in direct physical contact with the electronic component and/or the carrier.

13. The package according to claim 1, wherein the further encapsulant defines part of an exterior outline of the package.

14. The package according to claim 1, wherein the encapsulant is configured for providing a higher time-dependent dielectric breakdown safety than the further encapsulant.

15. The package according to claim 1, comprising at least one of the following features:
wherein the encapsulant is configured for providing a higher high-voltage safety than the further encapsulant;
wherein the electrically conductive particles comprise at least one of carbon black, titanium oxide, and crystalline petroleum coke;
wherein the electrically conductive particles have an electric conductivity of at least 0.01 S/cm, in particular at least 0.1 S/cm, more particularly in a range from 0.05 S/cm to 500 S/cm;
wherein the encapsulant is free of a low stress additive;
wherein the encapsulant comprises uncoated filler particles;
wherein part of the carrier is exposed beyond the encapsulant and beyond the further encapsulant;
wherein the encapsulant comprises an electrostatic dissipative material, wherein for example the electrostatic dissipative material comprises at least one of electrically conductive particles bound to segments of an epoxy backbone of material of the encapsulant, and short electrically conductive moieties reacted with epoxy material of the encapsulant;
wherein the electronic component comprises a semiconductor chip, for example a power semiconductor chip.

16. A method of manufacturing a package, the method comprising:
mounting an electronic component on a carrier;
at least partially encapsulating the electronic component and the carrier by an encapsulant which comprises not more than 0.1 weight percent, in relation to an entire weight of the encapsulant, of electrically conductive particles; and
forming a further encapsulant at an exterior surface of at least part of the encapsulant, wherein the further encapsulant has a larger amount of electrically conductive material than the encapsulant.

17. The method according to claim 16, wherein the method comprises at least one of the following features:
forming the further encapsulant by molding on at least part of the encapsulant;
forming the further encapsulant by coating at least part of the encapsulant, for example by painting, spraying, depositing, and/or dipping.

18. The method according to claim 16, wherein the method comprises forming the further encapsulant by modifying a surface portion of the encapsulant.

19. The method according to claim 18, wherein modifying the surface portion of the encapsulant is carried out by at least one of:
ultraviolet radiation-triggered carbonization;
treating by a laser;
treating by an electron beam;
phase separation based on hydrophobicity;
flaming;
burning; and
oxidizing.

20. The method according to claim 16, wherein the method comprises forming the further encapsulant before forming the encapsulant.
